(19) United States
(12) Patent Application Publication
(10) Pub. No.: US 2026/0255799 A1
(43) Pub. Date: Aug. 27, 2026

(54) DISPLAY DEVICE

(71) Applicant: LG Display Co., Ltd., Seoul (KR)

(72) Inventors: UnSang Yu, Paju-si (KR); JaeKyu Park, Paju-si (KR); Youngwoo Jo, Paju-si (KR); KiYol Chong, Paju-si (KR)

(21) Appl. No.: 19/424,140

(22) Filed: Dec. 18, 2025

(30) Foreign Application Priority Data
Feb. 27, 2025 (KR) 10-2025-0026016

(51) Int. Cl. H10K 59/121; G09G 3/00; G09G 3/3233

(52) U.S. Cl. CPC H10K 59/1213; G09G 3/006; G09G 3/3233; G09G 2300/0426; G09G 2300/0842; G09G 2330/08; G09G 2330/10; G09G 2330/12

(57) ABSTRACT

A display device includes a substrate including a display area and a non-display area outside the display area, a display panel disposed on the substrate in the display area, the display panel including a plurality of sub-pixels, a data driving circuit for driving the plurality of sub-pixels, and a redundancy cell disposed on the substrate in the non-display area, the redundancy cell for driving the plurality of sub-pixels. The display panel includes a first sub-pixel including a first light-emitting device and a driving transistor for driving the first light-emitting device, and the redundancy cell includes a first redundancy cell block including a first switch electrically connected to the first light-emitting device, and a first redundancy sub-pixel electrically connected to the first switch, the redundancy cell for driving the first light-emitting device.

### CROSS REFERENCE TO RELATED APPLICATION

This application claims priority from and the benefit of Korean Patent Application No. 10-2025-0026016, filed on February 27, 2025, which is hereby incorporated by reference for all purposes as if fully set forth herein.

### BACKGROUND

### Field

Embodiments of the invention relate generally to a display device.

### Discussion of The Background

As an information-oriented society has developed, demand for display devices for displaying images has increased in various forms, and recently, various display devices such as liquid crystal display devices and organic light-emitting display devices have been utilized.

A display device may include a plurality of sub-pixels. When some of the plurality of sub-pixels are defective, the corresponding sub-pixels may be displayed as dark spots or bright spots.

The above information disclosed in this Background section is only for understanding of the background of the inventive concept, and, therefore, it may contain information that does not constitute prior art.

### SUMMARY

Embodiments of the invention may provide a display device capable of improving image quality of a display panel through a redundancy cell.

Embodiments of the invention may provide a display device capable of driving a sub-pixel in a defective state through a redundancy cell.

Embodiments of the invention may provide a display device capable of low power consumption by driving a sub-pixel in a defective state.

Embodiments of the invention may provide a display device capable of process optimization by arranging components disposed on a silicon substrate using the same process.

Additional features of the inventive concepts will be set forth in the description which follows, and in part will be apparent from the description, or may be learned by practice of the inventive concepts. Embodiments of the invention are not limited to those described herein, and other features not mentioned will be clearly understood by those skilled in the art from the following description.

According to an embodiment of the invention, a display device includes a substrate including a display area and a non-display area outside the display area, a display panel disposed on the substrate in the display area, the display panel including a plurality of sub-pixels, a data driving circuit for driving the plurality of sub-pixels, and a redundancy cell disposed on the substrate in the non-display area, the redundancy cell for driving the plurality of sub-pixels. The display panel may include a first sub-pixel including a first light-emitting device and a driving transistor for driving the first light-emitting device, and the redundancy cell may include a first redundancy cell block including a first switch electrically connected to the first light-emitting device and a first redundancy sub-pixel electrically connected to the first switch, of the redundancy cell for driving the first light-emitting device.

The first switch may be electrically connected to the redundancy sub-pixel through a first connection line, and the first redundancy sub-pixel includes a first redundancy transistor electrically connected to the first connection line and a first driving voltage line, a second redundancy transistor electrically connected to a gate node of the first redundancy transistor and a data line, a third redundancy transistor electrically connected between the first connection line and a sensing line, and a redundancy capacitor electrically connected between the gate node of the first redundancy transistor and the first connection line.

When the first sub-pixel is a defective sub-pixel, the first switch may electrically connect the first light-emitting device and the first redundancy sub-pixel, and the first redundancy sub-pixel may supply a driving current to the first light-emitting device of the defective sub-pixel.

When the redundancy sub-pixel drives the first light-emitting device, the driving transistor may supply a current capable of causing the first light-emitting device to emit light.

The first sub-pixel may further include a scan transistor electrically connected between a gate node of the driving transistor and a data line, a sensing transistor electrically connected between the first light-emitting device and a sensing line, and a storage capacitor electrically connected between the gate node of the driving transistor and the first light-emitting device.

When the redundancy sub-pixel supplies the driving current to the first light-emitting device, at least one of the scan transistor and the sensing transistor may be in a turn-off state.

The defective sub-pixel may have at least one defect among the driving transistor, the scan transistor, the sensing transistor, the first light-emitting device, and the storage capacitor.

The redundancy cell may include a plurality of redundancy cell blocks, wherein the first redundancy cell block is electrically connected to the first sub-pixel, and wherein a second redundancy cell block may be electrically connected to a second sub-pixel and include a second switch different from the first switch and a second redundancy sub-pixel different from the first redundancy sub-pixel.

The number of redundancy cell blocks in the plurality of redundancy cell blocks may be equal to or less than the number of sub-pixels in the plurality of sub-pixels.

A read-out circuit may be disposed on the substrate, the read-out circuit receiving a current from the plurality of sub-pixels and sensing the current, and a microprocessor may be disposed on the substrate and controlling the read-out circuit and the display panel.

The substrate may include a silicon material, wherein the microprocessor may include a first transistor formed on the substrate, wherein the read-out circuit may include a second transistor formed on the substrate, wherein the display panel may include the driving transistor formed on the substrate, and wherein the display device may further comprise a first insulating layer disposed on the substrate, a first via electrode electrically connected to the first transistor and disposed in the first insulating layer, a second via electrode electrically connected to the second transistor and disposed in the first insulating layer, and a third via electrode electrically connected to the driving transistor and disposed in the first insulating layer.

An anode may be electrically connected to the third via electrode, a light-emitting layer may be disposed on the anode, a cathode may be disposed on the light-emitting layer, a color filter may be disposed on the cathode, and a microlens may be disposed on and overlapping the color filter

The first sub-pixel may further include a first protection device electrically connected between the first light-emitting device and the driving transistor.

When the first sub-pixel is determined to be a defective sub-pixel, the first protection device electrically may isolate the first light-emitting device from the driving transistor.

The first protection device may be for disconnecting an electrical connection between the first light-emitting device and the driving transistor through electrical control.

The first sub-pixel may be driven in a first driving period for displaying an image and a second driving period for detecting whether the first sub-pixel is defective.

The second driving period may include a first period in which a test voltage is supplied to the first sub-pixel, a second period in which the read-out circuit receives a test current from the first sub-pixel, and a third period in which the first sub-pixel is determined to be defective through test data generated based on the test current.

When the first sub-pixel is determined to be a defective sub-pixel, a microprocessor may store a coordinate at which the first sub-pixel is located, wherein the microprocessor may transmit a signal to the first protection device of the first sub-pixel such that the first protection device disconnects an electrical connection between the first light-emitting device and the driving transistor, and wherein the microprocessor may control the first switch to be in a turn-on state such that the first redundancy sub-pixel is electrically connected to the first light-emitting device.

The first sub-pixel may further include a second light-emitting device driven by the driving transistor, a second sensing transistor electrically connected between the second light-emitting device and a sensing line, and a second protection device electrically connected between the second light-emitting device and the driving transistor, and wherein the first redundancy cell block may further includes a second switch electrically connected between the first redundancy sub-pixel and the second light-emitting device.

The first protection device may be in a state in which the electrical connection between the driving transistor and the first light-emitting device is disconnected, or the second protection device is in a state in which the electrical connection between the driving transistor and the second light-emitting device is disconnected.

According to an embodiment of the invention, a method of determining a defective sub-pixel in a display device may include forming a substrate including a display area and a non-display area outside the display area, forming a display panel on the substrate in the display area, the display panel including a plurality of sub-pixels including a first light-emitting device and a driving transistor for driving the first light-emitting device, forming a redundancy cell on the substrate in the non-display area, the redundancy cell for driving the plurality of sub-pixels, driving a first sub-pixel of the plurality of sub-pixels in a first driving period for displaying an image, and driving the first sub-pixel in a second driving period for detecting whether the first sub-pixel is defective, wherein the redundancy cell may include a first redundancy cell block including a first switch electrically connected to the first light-emitting device, and a first redundancy sub-pixel electrically connected to the first switch, the redundancy cell for driving the first light-emitting device, wherein, when the first sub-pixel is determined to be a defective sub-pixel, the first redundancy sub-pixel may be electrically connected to the first light-emitting device.

Connecting the first switch to the redundancy sub-pixel through a first connection line, wherein the first redundancy sub-pixel may include a first redundancy transistor electrically connected to the first connection line and a first driving voltage line, a second redundancy transistor electrically connected to a gate node of the first redundancy transistor and a data line, a third redundancy transistor electrically connected between the first connection line and a sensing line, and a redundancy capacitor electrically connected between the gate node of the first redundancy transistor and the first connection line.

When the first sub-pixel is a defective sub-pixel, the first switch may electrically connect the first light-emitting device and the first redundancy sub-pixel, and the first redundancy sub-pixel may supply a driving current to the first light-emitting device of the defective sub-pixel.

The method may further include forming a read-out circuit on the substrate and forming a microprocessor on the substrate, the microprocessor may control the read-out circuit and the display panel, wherein the read-out circuit may receive a current from the plurality of sub-pixels and sense the current.

The second driving period may include supplying a test voltage to the first sub-pixel during a first period, receiving a test current from the first sub-pixel by the read-out circuit during a second period, and determining the first sub-pixel to be defective through test data generated based on the test current during a third period.

When the first sub-pixel is determined to be a defective sub-pixel, the method may further include storing a coordinate at which the first sub-pixel is located by the microprocessor, transmitting a signal by the microprocessor to the first protection device of the first sub-pixel such that the first protection device disconnects an electrical connection between the first light-emitting device and the driving transistor, and controlling the first switch to be in a turn-on state by the microprocessor, such that the first redundancy sub-pixel is electrically connected to the first light-emitting device.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a block diagram of a display device according to an embodiment of the invention.

FIG. 2 is an equivalent circuit diagram of a sub-pixel according to an embodiment of the invention.

FIG. 3 is a diagram illustrating a sub-pixel and a redundancy cell according to an embodiment of the invention.

FIG. 4 is a diagram illustrating a redundancy sub-pixel according to an embodiment of the invention.

FIG. 5 is a diagram illustrating a plurality of redundancy cells and sub-pixel blocks according to an embodiment of the invention.

FIG. 6 and FIG. 7 are cross-sectional views of an A-B area, a C-D area, and an E-F area as shown in FIG. 1.

FIG. 8 is another diagram illustrating a sub-pixel according to an embodiment of the invention.

FIG. 9 is another diagram illustrating a sub-pixel according to an embodiment of the invention.

FIG. 10 is a schematic perspectivediagram of the display device 100 according to embodiments of the present disclosure.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting”, “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element "is connected or coupled to", “contacts or overlaps” etc. a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc. each other via a fourth element. Here, the second element may be included in at least one of two or more elements that "are connected or coupled to", “contact or overlap”, etc. each other.

When time relative terms, such as "after," "subsequent to," "next," "before," and the like, are used to describe processes or operations of elements or configurations, or flows or steps in operating, processing, manufacturing methods, these terms may be used to describe non-consecutive or non-sequential processes or operations unless the term "directly" or "immediately" is used together.

In addition, when any dimensions, relative sizes etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to the accompanying drawings.

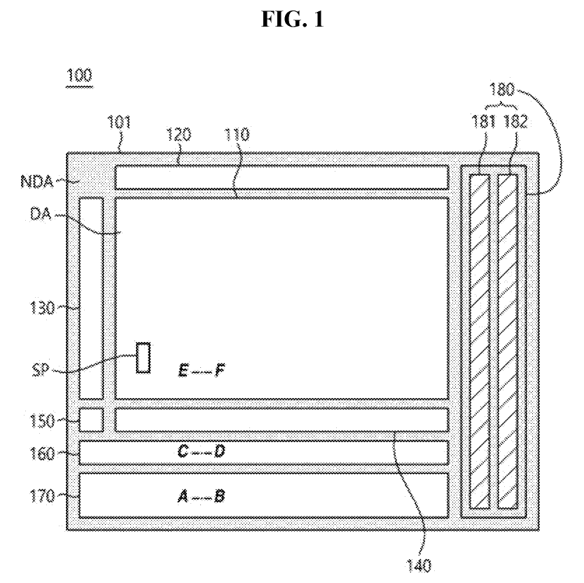

FIG. 1 is a block diagram of a display device according to an embodiment of the invention.

The display device 100 may include a display panel 110, a data driving circuit 120, a gate driving circuit 130, a controller 140, a power circuit 150, a read-out circuit 160, a microprocessor 170, and a redundancy cell 180.

The display panel 110, the data driving circuit 120, the gate driving circuit 130, the controller 140, the power circuit 150, the read-out circuit 160, the microprocessor 170, and the redundancy cell 180 may be disposed on a substrate 101. The substrate 101 may include a silicon material. When a light-emitting device ED disposed on the display panel 110 is an organic light-emitting device (OLED), the display device 100 may be referred to as “OLEDoS.”

The display panel 110 may display an image on a frame-by-frame basis. The display panel 110 may include a plurality of sub-pixels SP. As each of the plurality of sub-pixels SP emits light, the display panel 110 may display an image. Each of the plurality of sub-pixels SP may be controlled by an external signal.

The data driving circuit 120 may supply a data voltage to the plurality of sub-pixels SP disposed in the display panel 110. The data driving circuit 120 may generate the data voltage based on image data. The data voltage may be supplied to a data line DL, and the sub-pixel SP electrically connected to the data line DL may receive the data voltage.

The gate driving circuit 130 may supply a scan signal to the plurality of sub-pixels SP disposed in the display panel 110. When the scan signal having a turn-on level is supplied to the sub-pixel SP, the corresponding sub-pixel SP may receive the data voltage.

The controller 140 may control the data driving circuit 120 and the gate driving circuit 130. The controller 140 may control a timing at which the data driving circuit 120 and the gate driving circuit 130 operate. The controller 140 may control the data driving circuit 120 and the gate driving circuit 130 to receive or output a specific signal at a specific timing.

The power circuit 150 may supply a voltage to components disposed in the display device 100. The power circuit 150 may generate various voltages based on a base power supply.

The read-out circuit 160 may sense a defective sub-pixel SP among the plurality of sub-pixels SP. The read-out circuit 160 may sequentially sense the plurality of sub-pixels SP to determine coordinates of the defective sub-pixel SP. The read-out circuit 160 may transmit a position of the defective sub-pixel SP to the microprocessor 170.

The microprocessor 170 may control the read-out circuit 160 and the redundancy cell 180. The microprocessor 170 may control how the read-out circuit 160 senses the defective sub-pixel SP. The microprocessor 170 may control an operation of the redundancy cell 180.

The redundancy cell 180 may drive the defective sub-pixel SP. The redundancy cell 180 may be disposed in a non-display area NDA. The display panel 110 may be disposed in a display area DA, and the non-display area NDA may be an area outside the display area DA.

The redundancy cell 180 may include a switching block 181 and a redundancy sub-pixel block 182. A circuit for driving the defective sub-pixel SP may be disposed in the redundancy sub-pixel block 182. The switching block 181 may control a connection between the redundancy sub-pixel block 182 and the defective sub-pixel SP.

Hereinafter, the sub-pixel SP and the redundancy cell 180 will be described in more detail.

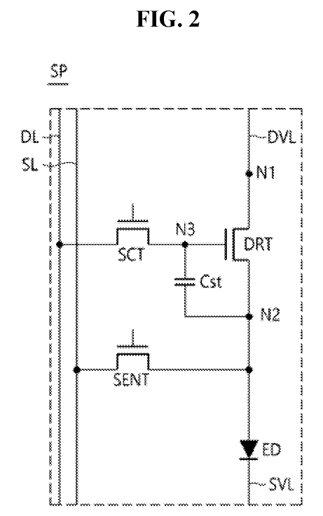

FIG. 2 is an equivalent circuit diagram of a sub-pixel SP according to an embodiment of the invention.

The sub-pixel SP may include a light-emitting device ED and components for driving the light-emitting device ED. The sub-pixel SP may control the light-emitting device ED so that the light-emitting device ED may emit light at a predetermined luminance. As each of the plurality of sub-pixels SP is controlled, a static image may be displayed through the display panel 110.

A driving transistor DRT may control a driving current flowing the light-emitting device ED. The driving transistor DRT may be electrically connected between a first node N1 and a second node N2. A gate node of the driving transistor DRT may be electrically connected to a third node N3. The first node N1 may be electrically connected to a driving voltage line DVL, and the second node N2 may be electrically connected to the light-emitting device ED.

A scan transistor SCT may control an input of the data voltage to the sub-pixel SP. The scan transistor SCT may be electrically connected between a data line DL and the third node N3. A scan signal may be supplied to the gate node of the scan transistor SCT. The scan signal may have a turn-on level for turning on the scan transistor SCT, or a turn-off level for turning off the scan transistor SCT.

A sensing transistor SENT may control an electrical connection between a sensing line SL and the second node N2. The sensing transistor SENT may be electrically connected between the sensing line SL and the second node N2. A sense signal may be supplied to a gate node of the sensing transistor SENT. The sense signal may have a turn-on level for turning on the sensing transistor SENT, or a turn-off level for turning off the sensing transistor SENT.

A storage capacitor Cst may store a voltage for the driving current. The storage capacitor Cst may be electrically connected between the second node N2 and the third node N3. A voltage corresponding to a difference between a voltage of the second node N2 and a voltage of the third node N3 may be stored in the storage capacitor Cst. The stored voltage may correspond to a gate-to-source voltage difference of the driving transistor DRT, and a magnitude of the driving current may be determined based on the voltage stored in the storage capacitor Cst.

The light-emitting device ED may emit light corresponding to a driving current. The light-emitting device ED may be electrically connected between the second node N2 and a base voltage line SVL. When a voltage is supplied across both ends of the light-emitting device ED and the driving current is supplied, the light-emitting device ED may emit light.

Meanwhile, when a defect occurs during a process of forming the sub-pixel SP, the sub-pixel SP may become a defective sub-pixel SP. When the sub-pixel SP becomes a defective sub-pixel SP, the sub-pixel SP may appear as a dark spot or a bright spot. The dark spot or the bright spot may be visually recognizable by a user, and the quality of the display panel 110 may deteriorate.

However, an embodiment of the invention may drive the light-emitting device ED included in the defective sub-pixel SP by using the redundancy cell 180, according to the description below.

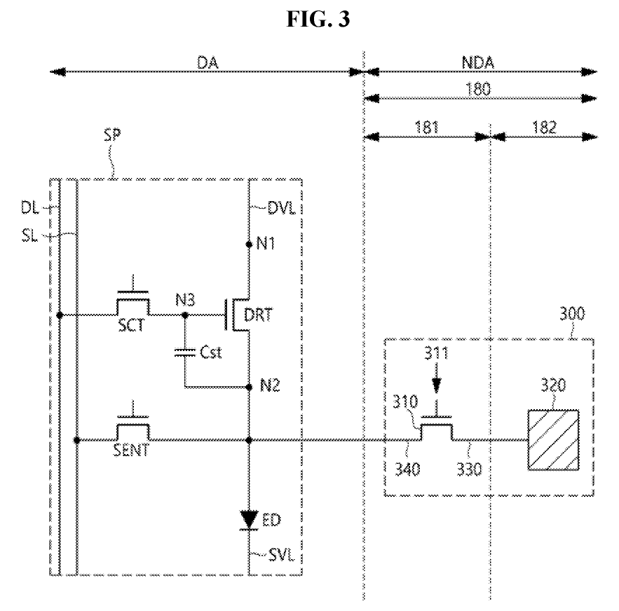

FIG. 3 is a diagram illustrating the sub-pixel SP and the redundancy cell 180 according to an embodiment of the invention. The sub-pixel SP shown in FIG. 3 may be the same as the sub-pixel SP shown in FIG. 2.

Referring to FIG. 3, the driving transistor DRT and the light-emitting device ED may be directly connected, but another component may be electrically connected between the driving transistor DRT and the light-emitting device ED. For example, an additional transistor or an electrical fuse may be connected between the driving transistor DRT and the light-emitting device ED.

The redundancy cell 180 may include a plurality of redundancy cell blocks 300. As shown in FIG. 3, only one redundancy cell block 300 is illustrated for convenience of explanation. According to an exemplary embodiment, one redundancy cell block 300 may be electrically connected to one sub-pixel SP.

The redundancy cell 180 may include a switching block 181 and a redundancy sub-pixel block 182. The switching block 181 may include a switch 310. The redundancy sub-pixel block 182 may include a redundancy sub-pixel 320.

The switch 310 may be in a turn-on state or a turn-off state according to a control signal 311 supplied to the switch 310. The redundancy sub-pixel 320 may drive the light-emitting device ED of the defective sub-pixel SP.

The switch 310 may be connected to the redundancy sub-pixel 320 through a first connection line 330. The switch 310 may be connected to the second node N2 of the sub-pixel SP through a second connection line 340.

Referring to FIG. 3, the switch 310 may be electrically connected to an anode of the light-emitting device ED. In the second node N2, the switch 310, the sensing transistor SENT, the driving transistor DRT, and the light-emitting device ED may be electrically connected to each other.

When the sub-pixel SP is a normal sub-pixel SP, a control signal 311 in a turn-off state may be supplied to the switch 310. That is, when the sub-pixel SP is a normal sub-pixel SP, the light-emitting device ED of the sub-pixel SP is not electrically connected to the redundancy sub-pixel 320.

The normal sub-pixel SP refers to a sub-pixel SP having no defect in components DRT, SCT, SENT, Cst, and ED, which are included in the sub-pixel SP. In the case of the normal sub-pixel SP, the transistors DRT, SCT, and SENT included in the normal sub-pixel SP may be controlled to meet their designed purposes. In addition, the light-emitting device ED included in the normal sub-pixel SP may emit light corresponding to image data.

The defective sub-pixel SP refers to a sub-pixel SP having a defect in at least one of components DRT, SCT, SENT, Cst, and ED. For example, when characteristic values of the transistors DRT, SCT, and SENT change from their intended values, turn-on and turn-off of the transistors DRT, SCT, and SENT may be abnormally controlled. In the case of the storage capacitor Cst, a voltage may be abnormally stored in the storage capacitor Cst, and thus, luminance of the light-emitting device ED may differ from a desired luminance. In the case of the light-emitting device ED, the light-emitting device ED may emit light at an abnormal luminance due to poor contact of an anode or a cathode, for example. When at least one of the components for enabling the light-emitting device ED to emit light is defective, the light-emitting device ED may fail to emit light. In addition, the sub-pixel SP may become the defective sub-pixel SP due to unintended electrical short-circuiting or an electrical opening among the components DRT, SCT, SENT, Cst, and ED included in the defective sub-pixel SP.

A method of determining the defective sub-pixel SP is described below. Determining the defective sub-pixel SP may be performed before a product is shipped or after the product is shipped. When the determination of the defective sub-pixel SP is performed after the product is shipped, a driving stage of the display device 100 may be divided into an image display period and a defective sub-pixel detection period. A method of detecting the defective sub-pixel SP will be described later.

When the sub-pixel SP is the defective sub-pixel SP, a control signal 311 in a turn-on state may be supplied to the switch 310. That is, the second node N2 of the defective sub-pixel SP may be electrically connected to the redundancy sub-pixel 320. Accordingly, the redundancy sub-pixel 320 may supply the driving current to the second node N2. In this case, the scan transistor SCT, the sensing transistor SENT, and the driving transistor DRT included in the defective sub-pixel SP may be maintained in a turn-off state. That is, the transistors included in the defective sub-pixel SP may be maintained in the turn-off state so as not to affect the light-emitting device ED.

However, at least one of the scan transistor SCT, the sensing transistor SENT, and the driving transistor DRT may be in a turn-on state. Because the storage capacitor Cst of the defective sub-pixel SP does not store a voltage for driving the light-emitting device ED, even if at least one of the scan transistor SCT, the sensing transistor SENT, and the driving transistor DRT is in a turn-on state, the light-emitting device ED may not be affected during light emission. That is, although the transistors SCT, SENT, and DRT may all be maintained in the turn-off state, even if at least one of the transistors SCT, SENT, and DRT is in a turn-on state, light emission from the light-emitting device ED may not be affected.

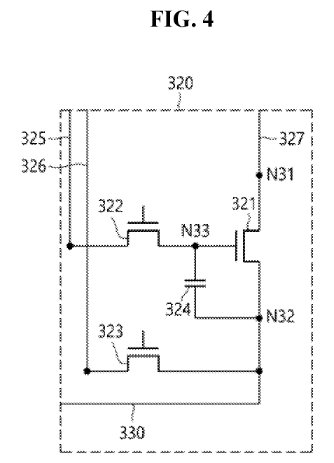

Hereinafter, an exemplary diagram of a specific structure of the redundancy sub-pixel 320 will be described. FIG. 4 is a diagram illustrating the redundancy sub-pixel 320 according to an embodiment of the invention.

Referring to FIG. 4, the redundancy sub-pixel 320 may include a first redundancy transistor 321, a second redundancy transistor 322, a third redundancy transistor 323, and a redundancy capacitor 324.

The first redundancy transistor 321 may control a driving current flowing to a second redundancy node N32. The first redundancy transistor 321 may be electrically connected between a first redundancy node N31 and the second redundancy node N32. The first redundancy node N31 may be electrically connected to a driving voltage line 327. The first redundancy transistor 321 may perform the same function as the driving transistor DRT illustrated in FIG. 2.

The second redundancy transistor 322 may control supply of a data voltage to a third redundancy node N33. The second redundancy transistor 322 may be electrically connected between a data line 325 and the third redundancy node N33. When the second redundancy transistor 322 is in a turn-on state, the data voltage may be supplied to the third redundancy node N33. The second redundancy transistor 322 may perform the same function as the scan transistor SCT illustrated in FIG. 2.

The third redundancy transistor 323 may control an electrical connection between a sensing line 326 and the second redundancy node N32. The third redundancy transistor 323 may be electrically connected between the sensing line 326 and the second redundancy node N32. The third redundancy transistor 323 may perform the same function as the sensing transistor SENT illustrated in FIG. 2.

The redundancy capacitor 324 may be electrically connected between the second redundancy node N32 and the third redundancy node N33. A voltage corresponding to a difference between a voltage of the second redundancy node N32 and a voltage of the third redundancy node N33 may be stored in the redundancy capacitor 324. The redundancy capacitor 324 may perform the same function as the storage capacitor Cst illustrated in FIG. 2.

A method of driving the redundancy sub-pixel 320 according to an exemplary embodiment will now be described. A plurality of sub-pixels SP may be electrically connected to a specific gate line, and at least one of the sub-pixels SP may be a defective sub-pixel SP, for example. When a turn-on scan signal is supplied to the specific gate line, the turn-on scan signal may also be supplied to a gate node of the second redundancy transistor 322. Then, a redundancy data voltage may be supplied to the third redundancy node N33, and a reference voltage may be supplied to the second redundancy node N32. A voltage corresponding to a difference between the redundancy data voltage and the redundancy reference voltage may be stored in the redundancy capacitor 324. Thereafter, a driving current corresponding to the voltage stored in the redundancy capacitor 324 may flow to the second redundancy node N32. That is, the driving current may be supplied to the light-emitting device ED of the at least one defective sub-pixel SP, and the light-emitting device ED of the at least one defective sub-pixel SP may emit light.

The above-described redundancy data voltage and redundancy reference voltage are the same voltages as the data voltage and reference voltage intended to be supplied to the defective sub-pixel SP. That is, the voltage that would have been supplied if the defective sub-pixel SP were a normal sub-pixel SP is supplied to the redundancy sub-pixel 320.

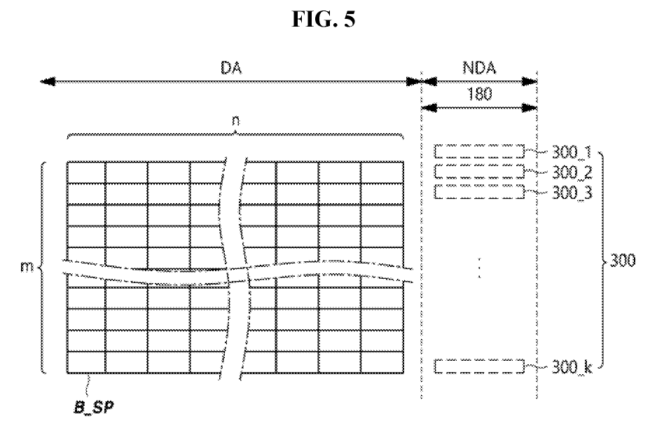

FIG. 5 is a diagram illustrating a plurality of redundancy cells 180 and sub-pixel blocks B_SP according to an embodiment of the invention.

Referring to FIG. 5, the plurality of sub-pixel blocks B_SP may be located in a display area DA. Each sub-pixel block B_SP corresponds to one sub-pixel SP illustrated in FIG. 2.

Referring to FIG. 5, the redundancy cell 180 may include a plurality of redundancy cell blocks 300_1, 300_2, 300_3, and 300_k. The plurality of redundancy cell blocks 300_1, 300_2, 300_3, and 300_k may be disposed in a non-display area NDA. The plurality of redundancy cell blocks 300_1, 300_2, 300_3, and 300_k may be arranged in a vertical line, but such arrangement is not limited thereto.

One sub-pixel block B_SP may be electrically connected to one redundancy cell block 300. That is, the sub-pixel block B_SP may be connected to the redundancy cell block 300 in a one-to-one relationship.

The sub-pixel blocks B_SP may be arranged in n units in a horizontal direction and in m units in a vertical direction. The redundancy cell blocks 300 may be arranged in k units. The number of sub-pixel blocks B_SP may be n * m, and the n * m sub-pixel blocks B_SP may correspond to the k redundancy cell blocks 300. However, such arrangement is not limited thereto, and two or more sub-pixel blocks B_SP may be electrically connected to one redundancy cell block 300, for example.

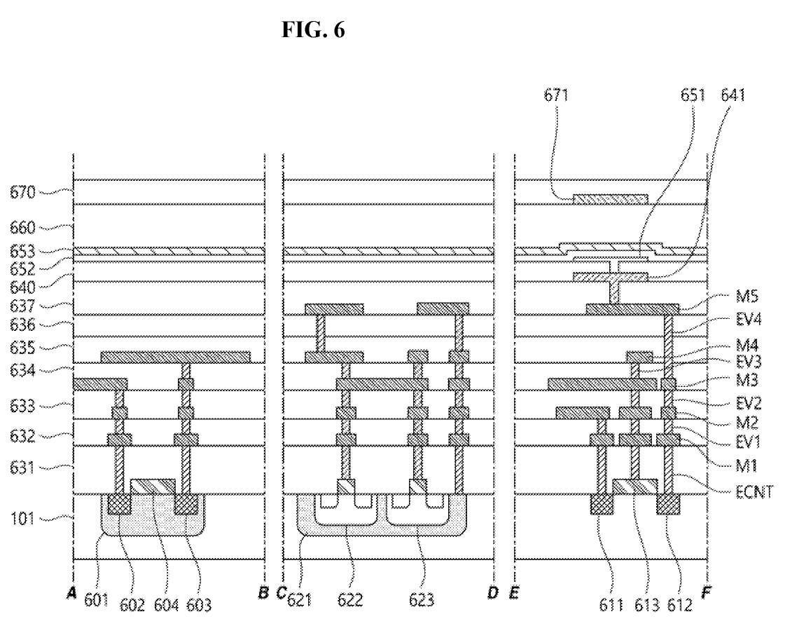

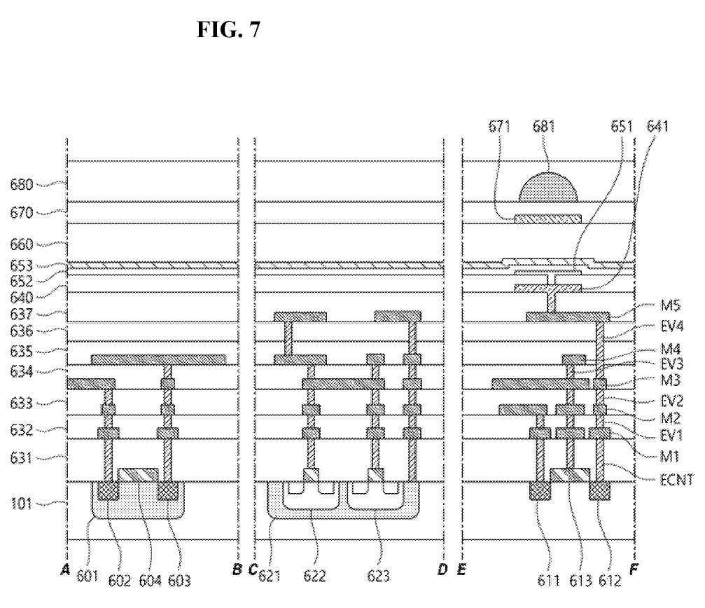

FIG. 6 and FIG. 7 are each cross-sectional views of an A-B area, a C-D area, and an E-F area, as illustrated in FIG. 1.

Referring to FIG. 6, cross-sectional views of the A-B area, the C-D area, and the E-F area may be identified, and these areas correspond to the cross-sectional views of the A-B area, the C-D area, and the E-F area illustrated in FIG. 1.

The A-B area corresponds to a part of the microprocessor 170. The C-D area corresponds to a part of the read-out circuit 160. The E-F area corresponds to a part of the display panel 110.

Referring to FIG. 6, components of the microprocessor 170, components of the read-out circuit 160, and components of the display panel 110 may be formed through a same process. For example, transistors included in each of the microprocessor 170, the read-out circuit 160, and the display panel 110 may be formed on the substrate 101. The substrate 101 may be a silicon substrate, and the transistors may be formed on the silicon substrate. Referring to FIG. 6, the transistors may be electrically connected to respective electrodes including at least portion of a contact electrode ECNT, a plurality of metal patterns M1 to M5, and a plurality of via electrodes EV1 to EV4. and respective electrodes may be formed in an insulating layer on the substrate 101.

Referring to the A-B area of FIG. 6, a first transistor is shown. Although the microprocessor 170 may include various components, for convenience of explanation, a cross-sectional view of the first transistor included in the microprocessor 170 will be described as an example. The first transistor may include a first body region 601, a first source region 602, a first drain region 603, and a first gate electrode 604. The first body region 601 may be of a negative type and may be referred to as an n-well. The first source region 602 and the first drain region 603 may be of a positive type and may be referred to as p-type high-concentration regions. The first gate electrode 604 may be an electrode to which a voltage for controlling the first transistor is supplied. The first transistor may be electrically connected to a first electrode including the contact electrode ECNT, the plurality of metal patterns M1 to M4, and the plurality of via electrodes EV1 to EV3.

Referring to the C-D area of FIG. 6, an inverter is shown. Although the read-out circuit 160 may include various components, for convenience of explanation, a cross-sectional view of the inverter included in the read-out circuit 160 will be described as an example. The inverter may include a deep negative well 621, a second transistor 622, and a third transistor 623. The second transistor 622 and the third transistor 623 may be formed in the deep negative well 621. Gate nodes of the second transistor 622 and the third transistor 623 may be electrically connected through the contact electrode ECNT, the plurality of metal patterns M1 to M5, and the plurality of via electrodes EV1 to EV4. For example, the second transistor 622 and the third transistor 623 may be electrically connected to a second electrode including the contact electrode ECNT, the plurality of metal patterns M1 to M5, and the plurality of via electrodes EV1 to EV4.

Referring to FIG. 6, a first insulating layer 631 may be disposed on the substrate 101. A contact electrode ECNT may be disposed inside the first insulating layer 631 and may electrically connect components disposed above and below the first insulating layer 631.

Referring to FIG. 6, a first metal pattern M1 may be disposed on the first insulating layer 631. A second insulating layer 632 may be disposed on the first insulating layer 631 and may be arranged to cover the first metal pattern M1. A first via electrode EV1 may be disposed inside the second insulating layer 632 and may electrically connect components disposed above and below the second insulating layer 632.

Referring to FIG. 6, a second metal pattern M2 may be disposed on the second insulating layer 632. A third insulating layer 633 may be disposed on the second insulating layer 632 and may be arranged to cover the second metal pattern M2. A second via electrode EV2 may be disposed inside the third insulating layer 633 and may electrically connect components disposed above and below the third insulating layer 633.

Referring to FIG. 6, a third metal pattern M3 may be disposed on the third insulating layer 633. A fourth insulating layer 634 may be disposed on the third insulating layer 633 and may be arranged to cover the third metal pattern M3. A third via electrode EV3 may be disposed inside the fourth insulating layer 634 and may electrically connect components disposed above and below the fourth insulating layer 634. The third via electrode EV3 may be electrically connected to the third metal pattern M3 and a fourth metal pattern M4.

Referring to FIG. 6, the fourth metal pattern M4 may be disposed on the fourth insulating layer 634. A fifth insulating layer 635 may be disposed on the fourth insulating layer 634 and may be arranged to cover the fourth metal pattern M4. A fourth via electrode EV4 may be disposed inside the fifth insulating layer 635 and may electrically connect components disposed above and below the fifth insulating layer 635. The fourth via electrode EV4 may be electrically connected to the third metal pattern M3 and a fifth metal pattern M5. The fourth via electrode EV4 may also be electrically connected to the fourth metal pattern M4 and the fifth metal pattern M5.

Referring to FIG. 6, a sixth insulating layer 636 may be disposed on the fifth insulating layer 635. Although no metal pattern is illustrated as being disposed on the fifth insulating layer 635, a metal pattern may be disposed thereon.

Referring to FIG. 6, the fifth metal pattern M5 may be disposed on the sixth insulating layer 636. A seventh insulating layer 637 may be disposed on the sixth insulating layer 636 and may be arranged to cover the fifth metal pattern M5. A connection electrode 641 may penetrate the seventh insulating layer 637 to be electrically connected to the fifth metal pattern M5.

Referring to FIG. 6, a planarization layer 640 may be disposed on the seventh insulating layer 637. An anode 651 may penetrate the planarization layer 640 to be electrically connected to the connection electrode 641. A light-emitting layer 652 may be disposed on the planarization layer 640. A cathode 653 may be disposed on the light-emitting layer 652. The magnitude of a driving current may be determined under control of the driving transistor DRT, and the driving current may be supplied to the anode 651 through the contact electrode ECNT, the plurality of metal patterns M1 to M5, the plurality of via electrodes EV1 to EV4, and the connection electrode 641. The light-emitting layer 652 may emit light corresponding to the driving current.

Referring to FIG. 6, an encapsulation layer 660 may be disposed on the cathode 653. The encapsulation layer 660 may prevent moisture from penetrating into the light-emitting layer 652 from outside. A color filter 671 may be disposed on the encapsulation layer 660. The color filter 671 may convert light passing therethrough into any one of red, green, and blue. A color filter insulating layer 670 may be disposed on the color filter 671. The color filter 671 may overlap the anode 651.

Referring to FIG. 7, a microlens 681 may be disposed on the color filter insulating layer 670. The microlens 681 may improve light-emission efficiency and may also widen a viewing angle. The microlens 681 may overlap the color filter 671. A protective layer 680 may be disposed on the color filter insulating layer 670, and the protective layer 680 may provide insulation and prevent moisture penetration.

Referring back to FIG. 6, cross-sectional views of the A-B area, the C-D area, and the E-F area have been described. As illustrated in FIG. 6, the transistors formed on the substrate 101, the contact electrodes ECNT, the plurality of metal patterns M1 to M5, and the plurality of via electrodes EV1 to EV4 may be formed through a same process. Accordingly, because the components of the microprocessor 170, the read-out circuit 160, and the display panel 110 may be simultaneously formed through the same process, the process efficiency thereof can be improved.

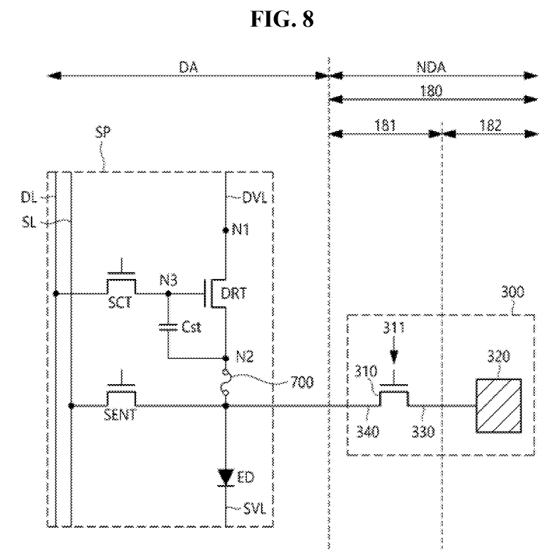

FIG. 8 is another example view of the sub-pixel SP according to an embodiment of the invention. Referring to FIG. 8, the redundancy cell block 300 may be the same as the redundancy cell block 300 illustrated in FIG. 2.

Referring to FIG. 8, the sub-pixel SP and the redundancy cell block 300 are shown. The sub-pixel SP illustrated in FIG. 8 may further include an electronic fuse 700 in addition to the components of the sub-pixel SP illustrated in FIG. 2.

Referring to FIG. 8, the electronic fuse 700 may be included between the second node N2 and the light-emitting device ED. The electronic fuse 700 may protect the sub-pixel SP from overcurrent, overvoltage, overheating, and the like. When a predetermined condition is satisfied, the electronic fuse 700 may change a connection between the second node N2 and the light-emitting device ED from a short-circuited state to an open state. This may be referred to as blowing the electronic fuse 700. The electronic fuse 700 may be a fuse or a protection device. In addition, the electronic fuse 700 is merely one example, and any device for disconnecting an electrical connection between the driving transistor DRT and the light-emitting device ED may correspond to the electronic fuse 700.

When the sub-pixel SP is determined to be a defective sub-pixel SP, the display device 100 may cause the electronic fuse 700 in the defective sub-pixel SP to be blown. After the electronic fuse 700 is blown, a turn-on signal 311 may be supplied to the switch 310. Then, the light-emitting device ED of the defective sub-pixel SP may be electrically connected to the redundancy sub-pixel 320. The redundancy sub-pixel 320 may supply a driving current to the light-emitting device ED of the defective sub-pixel SP, and the light-emitting device ED of the defective sub-pixel SP may emit light corresponding to the driving current.

A method of determining a defective sub-pixel SP is described below. The determination of the defective sub-pixel SP may be performed before shipment of the product or after shipment of the product. When the determination of a defective sub-pixel SP is performed after shipment of the product, a driving stage of the display device 100 may be divided into an image display period and a defective sub-pixel detection period.

The image display period may be a period for displaying an image through the display panel 110. The defective sub-pixel detection period may be performed between image display periods. The defective sub-pixel detection period may include a voltage supply stage, a defective current measurement stage, and a defective sub-pixel determination stage.

The voltage supply stage may be a stage in which a test voltage is supplied to a data line DL of a sub-pixel SP to be inspected, and a test base voltage is supplied to a sensing line SL.

The defective current measurement stage may be a stage in which, based on the voltage supplied in the voltage supply stage, the driving transistor DRT supplies a test driving current to the second node N2. The test driving current may flow through the sensing line SL. The read-out circuit 160 may be electrically connected to the sensing line SL. The read-out circuit 160 may convert the test driving current from an analog voltage state to a digital state. The test driving current may be converted into test data, and the test data may be delivered from the read-out circuit 160 to the microprocessor 170.

The defective sub-pixel determination stage may be a stage of determining whether the sub-pixel SP is a defective sub-pixel SP based on the test driving current. When the sub-pixel SP is determined to be a defective sub-pixel SP in the defective sub-pixel determination stage, a coordinate of the sub-pixel SP may be stored in the microprocessor 170. After storing the coordinate of the defective sub-pixel SP, the microprocessor 170 may control the switch 310 such that the defective sub-pixel SP is electrically connected to the redundancy sub-pixel 320.

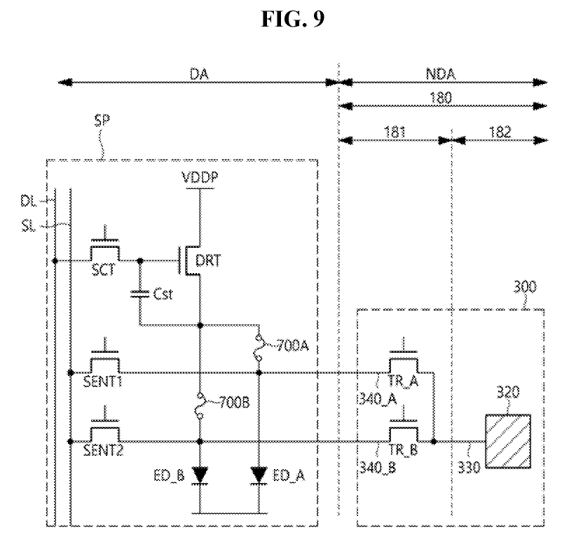

FIG. 9 is another example view of the sub-pixel SP according to an embodiment of the invention. Referring to FIG. 9, the sub-pixel SP and a redundancy cell block 300 electrically connected to the sub-pixel SP is shown.

Referring to FIG. 9, the sub-pixel SP may include one driving transistor DRT, one scan transistor SCT, two sensing transistors SENT1 and SENT2, two electronic fuses 700A and 700B, and two light-emitting devices ED_A and ED_B.

Referring to FIG. 9, the redundancy cell block 300 may include two switches TR_A and TR_B, and the redundancy sub-pixel 320. Each of the two switches TR_A and TR_B may be electrically connected to the redundancy sub-pixel 320 through a first connection line 330.

Referring to FIG. 9, the first electronic fuse 700A may be electrically connected to the first light-emitting device ED_A. The first electronic fuse 700A and the first light-emitting device ED_A may be electrically connected to the first switch TR_A through an A connection line 340_A. The first switch TR_A may be electrically connected to the redundancy sub-pixel 320.

Referring to FIG. 9, the second electronic fuse 700B may be electrically connected to the second light-emitting device ED_B. The second electronic fuse 700B and the second light-emitting device ED_B may be electrically connected to the second switch TR_B through a B connection line 340_B. The second switch TR_B may be electrically connected to the redundancy sub-pixel 320.

A method of controlling the first electronic fuse 700A and the second electronic fuse 700B illustrated in FIG. 9 may be the same as the method of controlling the electronic fuse 700 illustrated in FIG. 8. Accordingly, repeated description thereof will be omitted.

A feature of the sub-pixel SP illustrated in FIG. 9 is as follows. The sub-pixel SP illustrated in FIG. 9 may include two light-emitting devices, the first light-emitting device ED_A and the second light-emitting device ED_B, or, generally, the light-emitting devices ED. Accordingly, even when any one of the light-emitting devices ED illustrated in FIG. 9 is defective, the remaining light-emitting device ED may be driven so that the sub-pixel SP emits light.

For example, the two light-emitting devices ED may be in a normal state. In this case, only one of the two light-emitting devices ED may operate, or both of the two light-emitting devices ED may emit light.

For example, one of the two light-emitting devices ED may be in a defective state. In this case, an electronic fuse 700 electrically connected to the defective light-emitting device ED may be brought into an open state, and only the remaining normal light-emitting device ED may operate. For example, the first electronic fuse 700A may be in a state in which the driving transistor DRT and the first light-emitting device ED_A are electrically disconnected from each other, and the second electronic fuse 700B may be in a state in which the driving transistor DRT and the second light-emitting device ED_B are electrically connected to each other. Alternatively, the first electronic fuse 700A may be in a state in which the driving transistor DRT and the first light-emitting device ED_A are electrically connected to each other, and the second electronic fuse 700B may be in a state in which the driving transistor DRT and the second light-emitting device ED_B are electrically disconnected from each other. That is, one of the first electronic fuse 700A and the second electronic fuse 700B may be in a blown state.

When both of the two light-emitting devices ED are in a defective state, the sub-pixel SP may appear as a dark spot. However, in this case, the luminance of an adjacent sub-pixel SP to the defective sub-pixel SP may increase, thereby compensating for the luminance reduction due to the defective sub-pixel SP. The above-described compensation feature is also applicable to the sub-pixel SP illustrated in FIG. 3 and FIG. 7.

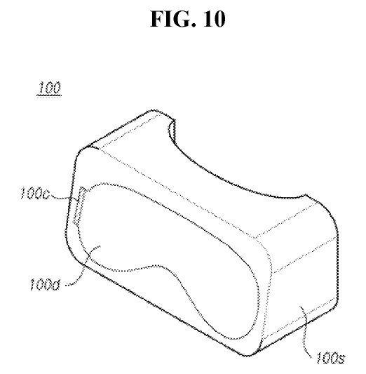

FIG. 10 is a schematic perspective diagram of the display device 100 according to embodiments of the present disclosure.

The display device 100 illustrated in FIG. 10 is one example of a display device, and the embodiments of the present disclosure are not limited to this form or this implementation method.

The display device 100 may be a display device to which a virtual reality (VR) system and an augmented reality (AR) system are applied.

The display device 100 to which a virtual reality (VR) system is applied may provide a virtual experience to a user by showing the user a virtual space, rather than the real world, through a display panel.

The display device 100 to which an augmented reality (AR) system is applied may provide a virtual experience based on the real world by showing a user both the real world and a virtual image.

A display panel included in a head mounted display (HMD), a face mounted display (FMD), or an eye glasses-type display (EGD) may be implemented in a curved display form having a predetermined curvature for implementing virtual reality (VR) and augmented reality (AR) technology. That is, the display device 100 may be in the form of a curved display having a predetermined curvature.

The display device 100 may include a display unit 100d, a circuit unit 100c, and a case unit 100s.

When the display device 100 includes only the above-described display unit 100d and circuit unit 100c, it may be a curved display device. The display device 100 may have a head mounted display (HMD) form in which the curved display device is combined with various types of case units.

The display device including the above-described display unit 100d, circuit unit 100c, and case unit 100s may be a wearable display device to which technologies other than a virtual reality system or an augmented reality system can be applied, and various other technologies may be incorporated therein. That is, depending on various purposes, the display unit 100d may output an image suitable for the corresponding purpose to a user.

The display unit 100d and the circuit unit 100c may be accommodated inside the case unit 100s. The display unit 100d may be disposed so as to be exposed to the outside of the case unit 100s.

The display panel may be driven by the circuit unit 100c.

The circuit unit 100c may include circuits for driving the display panel.

The circuit unit 100c may be disposed at a side of the display unit 100d. The circuit unit 100c may be disposed on the substrate 101 (see FIGS. 6 and 7) of the display unit 100d illustrated in FIG. 10. However, the present disclosure is not limited thereto, and the circuit unit 100c may be disposed on an upper portion of another component of the display unit 100d. In addition, the circuit unit 100c may be disposed inside the case unit 100s. The circuit unit 100c may be disposed anywhere, provided that it is in an area that does not display an image.

The circuit unit 100c may include a data driving circuit and a gate driving circuit, and may further include a controller for controlling the data driving circuit and the gate driving circuit.

The data driving circuit may be a circuit for driving a plurality of data lines, and may supply data signals to the plurality of data lines. The gate driving circuit may be a circuit for driving a plurality of gate lines, and may supply gate signals to the plurality of gate lines.

The gate driving circuit, under the control of the controller, may output a gate signal having a turn-on level voltage or a gate signal having a turn-off level voltage. The gate driving circuit may sequentially supply gate signals having a turn-on level voltage to the plurality of gate lines so as to sequentially drive the plurality of gate lines.

The controller may supply a data control signal (DCS) to the data driving circuit in order to control an operation timing of the data driving circuit. The controller may supply a gate control signal (GCS) to the gate driving circuit in order to control an operation timing of the gate driving circuit.

The controller, according to the implementation timing of each frame, may initiate scanning, convert input image data input from the outside into a data signal format usable by the data driving circuit, supply the converted image data (Data) to the data driving circuit, and control data driving at an appropriate time in synchronization with the scanning.

The controller may receive timing signals such as a vertical synchronization signal (Vsync), a horizontal synchronization signal (Hsync), an input data enable signal (DE), and a clock signal (CLK) in order to control the data driving circuit and the gate driving circuit, generate various control signals (DCS, GCS), and output the control signals to the data driving circuit and the gate driving circuit.

The case unit 100s may protect the display unit 100d and the circuit unit 100c, and the display unit 100d and the circuit unit 100c may be fixed to the case unit 100s.

The case unit 100s may be connected to a band (not illustrated) for fixing the display device 100 to a user’s face.

The display device according to embodiments of the present disclosure may be described as follows.

The embodiments of the present disclosure may provide a display device including a substrate including a display area and a non-display area outside the display area; a display panel disposed on the substrate, disposed in the display area, and including a plurality of sub-pixels; a data driving circuit for driving the plurality of sub-pixels; and a redundancy cell disposed on the substrate, disposed in the non-display area, and capable of driving the plurality of sub-pixels, wherein the display panel includes a first sub-pixel including a first light-emitting device and a driving transistor for driving the first light-emitting device, and the redundancy cell includes a first redundancy cell block including a first switch electrically connected to the first light-emitting device, and a first redundancy sub-pixel electrically connected to the first switch and capable of driving the first light-emitting device.

The switch may be electrically connected to the redundancy sub-pixel through a first connection line, and the redundancy sub-pixel may include: a first redundancy transistor electrically connected to the first connection line and a first driving voltage line; a second redundancy transistor electrically connected to a gate node of the first redundancy transistor and to a data line; a third redundancy transistor electrically connected between the first connection line and a sensing line; and a redundancy capacitor electrically connected between the gate node of the first redundancy transistor and the first connection line.

The first sub-pixel may be a defective sub-pixel, the switch may electrically connect the first light-emitting device and the redundancy sub-pixel, and the redundancy sub-pixel may supply a driving current to the first light-emitting device of the defective sub-pixel.

When the redundancy sub-pixel drives the first light-emitting device, the driving transistor may not supply a current capable of causing the first light-emitting device to emit light.

The first sub-pixel may further include a scan transistor electrically connected between a gate node of the driving transistor and a data line; a sensing transistor electrically connected between the first light-emitting device and a sensing line; and a storage capacitor electrically connected between the gate node of the driving transistor and the first light-emitting device.

When the redundancy sub-pixel supplies the driving current to the first light-emitting device, at least one of the scan transistor and the sensing transistor may be in a turn-off state.

The defective sub-pixel may have at least one defect among the driving transistor, the scan transistor, the sensing transistor, the first light-emitting device, and the storage capacitor.

The redundancy cell may include a plurality of redundancy cell blocks, wherein the first redundancy cell block is electrically connected to the first sub-pixel, a second redundancy cell block is electrically connected to a second sub-pixel, and the second redundancy cell block includes a second switch different from the first switch and a second redundancy sub-pixel different from the first redundancy sub-pixel.

The number of the plurality of redundancy cell blocks may be equal to or less than the number of the plurality of sub-pixels.

The display device may further include a read-out circuit disposed on the substrate and receiving a current from the plurality of sub-pixels to sense the current, and a microprocessor disposed on the substrate and controlling the read-out circuit and the display panel.

The substrate may include a silicon material, the microprocessor may include a first transistor formed on the substrate, the read-out circuit may include a second transistor formed on the substrate, the display panel may include the driving transistor formed on the substrate, and the display device may further comprise: a first insulating layer disposed on the substrate; a first via electrode electrically connected to the first transistor and disposed in the first insulating layer; a second via electrode electrically connected to the second transistor and disposed in the first insulating layer; and a third via electrode electrically connected to the driving transistor and disposed in the first insulating layer.

The display device may further include an anode electrically connected to the third via electrode, a light-emitting layer disposed on the anode, a cathode disposed on the light-emitting layer, a color filter disposed on the cathode, and a microlens disposed on the color filter and overlapping the color filter.

The first sub-pixel may further include a first protection device electrically connected between the first light-emitting device and the driving transistor.

When the first sub-pixel is determined to be a defective sub-pixel, the first protection device may electrically isolate the first light-emitting device from the driving transistor.

The first protection device may disconnect an electrical connection between the first light-emitting device and the driving transistor through electrical control.

The first sub-pixel may be driven in a first driving period for displaying an image and a second driving period for detecting whether the first sub-pixel is defective.

The second driving period may include: a first period in which a test voltage is supplied to the first sub-pixel; a second period in which the read-out circuit receives a test current from the first sub-pixel; and a third period in which defectiveness of the first sub-pixel is determined through test data generated based on the test current.

When the microprocessor determines the first sub-pixel to be a defective sub-pixel, the microprocessor may store a coordinate at which the first sub-pixel is located.

The microprocessor may transmit a signal to the first protection device of the first sub-pixel such that the first protection device disconnects an electrical connection between the first light-emitting device and the driving transistor, and the microprocessor may control the first switch to be in a turn-on state such that the first redundancy sub-pixel is electrically connected to the first light-emitting device.

The first sub-pixel may further include a second light-emitting device driven by the driving transistor, a second sensing transistor electrically connected between the second light-emitting device and a sensing line, and a second protection device electrically connected between the second light-emitting device and the driving transistor, and the first redundancy cell block may further include a second switch electrically connected between the first redundancy sub-pixel and the second light-emitting device.

The first protection device may be in a state in which the electrical connection between the driving transistor and the first light-emitting device is disconnected, or the second protection device may be in a state in which the electrical connection between the driving transistor and the second light-emitting device is disconnected.

The above description has been presented to enable any person skilled in the art to make and use the technical idea of the present invention, and has been provided in the context of a particular application and its requirements. Various modifications, additions, and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a substrate including a display area and a non-display area outside the display area;
a display panel disposed on the substrate in the display area, the display panel including a plurality of sub-pixels;
a data driving circuit for driving the plurality of sub-pixels; and
a redundancy cell disposed on the substrate in the non-display area, the redundancy cell for driving the plurality of sub-pixels,
wherein the plurality of sub-pixels includes a first sub-pixel including a first light-emitting device and a driving transistor for driving the first light-emitting device, and
wherein the redundancy cell includes a first redundancy cell block including a first switch electrically connected to the first light-emitting device, and a first redundancy sub-pixel electrically connected to the first switch, the redundancy cell for driving the first light-emitting device.

2. The display device according to claim 1, wherein the first switch is electrically connected to the first redundancy sub-pixel through a first connection line, and
wherein the first redundancy sub-pixel includes:
a first redundancy transistor electrically connected to the first connection line and a first driving voltage line;
a second redundancy transistor electrically connected to a gate node of the first redundancy transistor and a data line;
a third redundancy transistor electrically connected between the first connection line and a sensing line; and
a redundancy capacitor electrically connected between the gate node of the first redundancy transistor and the first connection line.

3. The display device according to claim 1, wherein when the first sub-pixel is a defective sub-pixel, the first switch electrically connects the first light-emitting device and the first redundancy sub-pixel, and
the first redundancy sub-pixel supplies a driving current to the first light-emitting device of the defective sub-pixel.

4. The display device according to claim 3, wherein, when the first redundancy sub-pixel drives the first light-emitting device, the driving transistor does not supply a current for causing the first light-emitting device to emit light.

5. The display device according to claim 4, wherein the first sub-pixel further includes:
a scan transistor electrically connected between a gate node of the driving transistor and a data line;
a sensing transistor electrically connected between the first light-emitting device and a sensing line; and
a storage capacitor electrically connected between the gate node of the driving transistor and the first light-emitting device.

6. The display device according to claim 5, wherein when the first redundancy sub-pixel supplies the driving current to the first light-emitting device, at least one of the scan transistor and the sensing transistor is in a turn-off state.

7. The display device according to claim 5, wherein the defective sub-pixel is a sub-pixelin which at least one of the driving transistor, the scan transistor, the sensing transistor, the first light-emitting device, and the storage capacitor is defective.

8. The display device according to claim 1, wherein the redundancy cell includes a plurality of redundancy cell blocks including the first redundancy cell block and a second redundancy cell block, and the plurality of sub-pixels further include a second sub-pixel,,
wherein the first redundancy cell block is electrically connected to the first sub-pixel, and
wherein the second redundancy cell block is electrically connected to the second sub-pixel and includes a second switch different from the first switch and a second redundancy sub-pixel different from the first redundancy sub-pixel.

9. The display device according to claim 8, wherein the number of redundancy cell blocks in the plurality of redundancy cell blocks is equal to or less than the number of sub-pixels in the plurality of sub-pixels.

10. The display device according to claim 1, further comprising:
a read-out circuit disposed on the substrate, the read-out circuit receiving a current from the plurality of sub-pixels and sensing the current; and
a microprocessor disposed on the substrate and controlling the read-out circuit and the display panel.

11. The display device according to claim 10, wherein the substrate includes a silicon material,
wherein the microprocessor includes a first transistor formed on the substrate,
wherein the read-out circuit includes a second transistor formed on the substrate,
wherein the driving transistor is formed on the substrate, and
wherein the display device further comprises:
an insulating layer disposed on the substrate;
a first electrode electrically connected to the first transistor and disposed in the insulating layer;
a second electrode electrically connected to the second transistor and disposed in the insulating layer; and
a third electrode electrically connected to the driving transistor and disposed in the insulating layer.

12. The display device according to claim 11, further comprising:
an anode electrically connected to the third electrode;
a light-emitting layer disposed on the anode;
a cathode disposed on the light-emitting layer;
a color filter disposed on the cathode; and
a microlens disposed on and overlapping the color filter.

13. The display device according to claim 11, wherein the first sub-pixel further includes a first protection device electrically connected between the first light-emitting device and the driving transistor.

14. The display device according to claim 13, wherein, when the first sub-pixel is determined to be a defective sub-pixel, the first protection device electrically isolates the first light-emitting device from the driving transistor.

15. The display device according to claim 13, wherein the first sub-pixel is driven in a first driving period for displaying an image and a second driving period for detecting whether the first sub-pixel is defective.

16. The display device according to claim 15, wherein the second driving period includes:
a first period in which a test voltage is supplied to the first sub-pixel;
a second period in which the read-out circuit receives a test current from the first sub-pixel; and
a third period in which the first sub-pixel is determined to be defective through test data generated based on the test current.

17. The display device according to claim 13, wherein the first sub-pixel further includes:
a second light-emitting device driven by the driving transistor;
a second sensing transistor electrically connected between the second light-emitting device and a sensing line; and
a second protection device electrically connected between the second light-emitting device and the driving transistor, and
wherein the first redundancy cell block further includes a second switch electrically connected between the first redundancy sub-pixel and the second light-emitting device.

18. The display device according to claim 11, wherein each of the first electrode to the third electrode includes a via electrode.

19. A method of determining a defective sub-pixel in a display device, the method comprising:
forming a substrate including a display area and a non-display area outside the display area;
forming a display panel on the substrate in the display area, the display panel including a plurality of sub-pixels including a first light-emitting device and a driving transistor for driving the first light-emitting device;
forming a redundancy cell on the substrate in the non-display area, the redundancy cell for driving the plurality of sub-pixels; and
driving a first sub-pixel of the plurality of sub-pixels in a first driving period for displaying an image, and driving the first sub-pixel in a second driving period for detecting whether the first sub-pixel is defective;
wherein the redundancy cell includes a first redundancy cell block including a first switch electrically connected to the first light-emitting device, and a first redundancy sub-pixel electrically connected to the first switch, the redundancy cell for driving the first light-emitting device, and
wherein, when the first sub-pixel is determined to be a defective sub-pixel, the first redundancy sub-pixel is electrically connected to the first light-emitting device.

20. The method of claim 19, further comprising connecting the first switch to the first redundancy sub-pixel through a first connection line,
wherein the first redundancy sub-pixel includes:
a first redundancy transistor electrically connected to the first connection line and a first driving voltage line;
a second redundancy transistor electrically connected to a gate node of the first redundancy transistor and a data line;
a third redundancy transistor electrically connected between the first connection line and a sensing line; and
a redundancy capacitor electrically connected between the gate node of the first redundancy transistor and the first connection line.
